(19) United States
(12) Patent Application Publication
(10) Pub. No.: US 2009/0208877 A1
(43) Pub. Date: Aug. 20, 2009

(54) METHODS OF MAKING OPTICAL FIBER GRATINGS

(75) Inventor: Adrian Carter, Bulli (AU)

Correspondence Address: NUFERN;Peter J. Rainville, 7 AIRPORT PARK ROAD, EAST GRANBY, CT, 06026, US

(73) Assignee: Nufern, East Granby, CT (US)

(21) Appl. No.: 12/347,269

(22) Filed: Dec. 31, 2008

Related U.S. Application Data
(62) Division of application No. 11/777,838, filed on Jul. 13, 2007.

(51) Int. Cl. G03F 7/20

(52) U.S. Cl. 430/321

(57) ABSTRACT

Optical fibers and optical fiber lasers including gratings and methods of writing gratings into fibers. A method can comprise providing a photosensitive optical fiber having a region having an original refractive index (RI) profile along the elongate direction of the fiber; exposing the optical fiber to actinic radiation to alter the original RI profile to form along a length of the fiber a grating having a RI profile including alternating higher RI and lower RI sections; and wherein the maximum RI difference between a RI of a higher RI section and a RI of an adjacent lower RI section of the grating RI profile is no greater than 85% of the difference between the average index of the grating RI profile and the original RI profile.

### CROSS-REFERENCE TO RELATED APPLICATIONS

The present application is a divisional of application Ser. No. 11/777,838, filed Jul. 13, 2007 and entitled “Optical Fiber Gratings For Handling Increased Power Levels and Methods of Making”. The foregoing application is incorporated herein by reference.

### FIELD OF THE INVENTION

The present invention relates to gratings and methods of writing gratings in optical waveguides, such as optical fibers.

### BACKGROUND

Gratings and methods of writing gratings into optical fibers are well-known, especially in applications relating to fiber optic telecommunications. Known gratings include short period gratings, such as fiber Bragg gratings (FBGs), which can highly reflect only a certain wavelength or wavelengths and transmit others largely unaffected, as well as long period gratings (LPGs), which can attenuate only a certain wavelength or wavelengths by directing them into another region of a fiber and transmit others largely unaffected.

Gratings can be written into a fiber via selective exposure of the fiber, such as from the side, with actinic radiation, such as, for example, ultraviolet light. The actinic radiation changes the refractive index of a photosensitive region of an optical fiber, such as, for example, a photosensitive core of an optical fiber. For example, the fiber can be exposed to actinic radiation comprising a pattern of alternating areas of higher and lower intensity. The areas of higher intensity change the refractive index of the photosensitive region more than the areas of lower intensity, writing in the fiber an elongate arrangement of alternating sections of higher and lower refractive index. One technique for writing a grating includes interposing a mask, such as a phase mask, between a radiation source and the fiber; another technique involves directing angled beams to interfere constructively and destructively at the fiber; and yet another technique involves scanning a beam, the extent of which is less than the grating length, along a length of a fiber and varying the intensity of the beam appropriately.

Physical properties of the grating, such as the index difference between the higher index and lower index sections (“delta n” or Δn), the spacing between successive higher index sections (“pitch” or Λ) and the length of the grating can be selected to provide desired spectral characteristics. Such spectral characteristics can include the wavelength of peak reflection, the degree of reflection at that wavelength and the bandwidth of the reflection spectrum. Gratings having higher index contrast between the lower index and higher index sections typically reflect more strongly for a given length of the grating. The photosensitivity of a fiber, which determines the index change for a given intensity and duration of exposure, can be enhanced via a variety of techniques, including doping the fiber with one or more of the many dopants known to provide photosensitivity (e.g., an oxide of germanium). The fiber can also be loaded with hydrogen or deuterium, as is known the art.

FBGs in particular have found extensive application in telecommunications. For example FBGs can be used to direct different wavelengths of light along different optical paths in the wavelength division multiplexed (WDM) technique, extensively employed to increase the bandwidth of a telecommunications system, wherein a single fiber carries many different optical channels of different wavelengths. As another example, an FBG can be used to wavelength stabilize relatively low power telecommunications laser diodes that are modulated to transmit information in a telecommunications system. Chirped FBGs can compensate for dispersion. LPGs are also useful, and can, for example, selectively attenuate amplified spontaneous emission in telecommunications fiber amplifiers.

More recently, gratings are being used in non-telecommunications applications, such as, for example, industrial fiber lasers or amplifiers. For example, FBGs can define the laser cavity in a rare earth doped fiber laser, an LPG can couple single mode light into a higher order mode having a larger effective area for amplification, or a grating can be blazed to couple pump light into or out of a fiber laser or amplifier. However, much of the known body of work on improving gratings concerns telecommunications issues, such, as for example, the design of athermal packages for minimizing changes in the peak reflection wavelength with changes in temperature in WDM to avoid interference between optical channels. Issues relating to the performance of gratings in, for example, industrial lasers or amplifiers have received far less attention.

### SUMMARY OF THE INVENTION

Whereas gratings, such as, for example, FBGs, have been used extensively in telecom applications (wherein power densities are relatively low) for many years, it is only recently that high power (>100 W) applications have come to the fore. Operation of some devices, such as lasers wherein FBGs define the lasing cavity, at continuous high powers or at high pulse energies have experimentally shown decreased power output over time. This is highly undesirable, especially if a product is to be commercially viable, and has lead to costly design modifications. For example, Applicant understands that in some products designers have incorporated extra pump diodes into a laser and control electronics to increase pump power to compensate for the increased losses that would otherwise decrease output power. This is costly, as pump diodes are often the most expensive components of a laser or amplifier.

It is considered that the decrease in output power can be due to the formation of “color centers” that change the refractive index (for simplicity at times referred to as “RI” herein) of glass, such as the core or cladding glass of one or more of the fibers of a fiber laser or amplifier. Color centers are caused by the changes to the defect structure of the glass network. Changes in the RI can cause changes (e.g., an increase) in the absorption properties of the glass, and hence reduced power output of the device, as is demonstrated by the Kramers-Kronig causality relationship. Applicant has noted that gratings are typically written using a pattern of intense actinic radiation, such as, for example, UV-light, that also induces changes to the local defect structure of the glass network. However, these changes are intended, controlled and desirable, as they induce the RI changes in the glass to form the grating during the grating writing process.

Without wishing to be bound by theory (except as regards a claim where a particular mechanism is explicitly recited), it is considered that changes in grating properties, namely the RI of the sections of the grating, may be responsible for the observed decreases in output power over time of higher power devices. Changes in the RI of the gratings sections can erase, or reduce, the Δn of the grating. A number of factors can relate erasure of a grating with a reduction of output power. Reducing grating reflectivity can allow leakage of power out of a laser cavity from one of the gratings, which is typically intended to be fully reflective; can produce less than optimal output coupling from the other of the gratings; and can result in an increase in optical loss due to increased absorption via the Kramers-Kronig relationship.

The grating can be erased via a reduction of the induced RI changes that form the higher RI sections via relaxation of the glass matrix host. Indeed it is well known that these desired index changes can undergo thermally induced decay. This often results in shifts in wavelength of the grating as well as decreases in the reflectivity and spectral bandwidth. The way typically employed in the prior art to address this issue is to “thermally stabilize” the gratings after formation and prior to their use by semi-annealing the grating at an elevated temperature for a short period of time after the grating is written. After annealing it is believed that the grating will only contain thermally stable sites (such that the less stable defect sites have been annealed) and long term stability is assured. Another approach to avoid erasure of the higher RI sections of the grating is to control the thermal properties of the fiber that includes the grating during operation of the actual device in which the grating is used. For example, the gratings can be maintained at or below 100° C., for example, in a fiber laser or amplifier. This can also help avoid thermal damage to the optical polymer coating of the fiber.

Applicant, however, considers that an additional process may be responsible, at least in part, for the decreased power transmission of high power devices. In addition to the erasure noted above by reducing the RI of the higher RI sections, the RI of the lower RI sections of the grating may be increasing during higher power operation, again tending to reduce Δn and erase the grating. It is possible that the lower RI sections of a grating are exposed to radiation generated during operation in such a manner that the RI in these regions increases to match or approach that of the higher RI sections. This is a wholly unintended, uncontrolled and undesirable additional “rewriting” of portions of the grating and would, of course, tend to erase the grating.

This selective rewriting of portions of the grating is unexpected, however, because devices are typically operated at wavelengths that are very different than those used in the deliberate writing of the grating. The wavelengths are typically several times longer and hence the associated photon energies lower. However, Applicant has realized that at high fluences either the pump radiation used to pump a fiber laser or the output radiation could induce, via a multiphonon process, further changes to the glass host RI. More specifically, as one example, it is possible that a 4 or 5 photon process involving circa 1100 nm radiation (the wavelength of operation of many high power devices) could result in radiation having a much shorter wavelength that is nearly the same as, and hence has nearly the same photon energy, as that used to controllably write the grating. This radiation will uncontrollably rewrite the glass and cause an index change. Because the lower RI sections of the gratings have typically not been exposed to actinic radiation during the controlled, desired writing of the gratings (or if they have, such exposure is in far less a dose than the high RI sections and is an undesirable artifact of certain writing processes), more photosensitive sites having a wider range of energies, including sites having “low” activation energies, are available. Thus the lower RI sections will be rewritten to a larger degree, meaning there will be a larger increase in the RI of the lower RI sections than in the higher RI sections, effectively causing erasure of the existing FBG. It should be noted that although color centers are only one possible model for the RI change, others including densification and structural rearrangement, the reasoning herein is considered to have applicability regardless of model, due at least in part to the general relationship between RI and loss described by the Kramers-Kronig relationship and other factors.

Accordingly, in one broad aspect of the invention, the RI profile of a grating used in a higher power device can include an offset wherein the RI of the lower RI sections, as well as of the higher RI sections, is changed, such as by being increased, over the original RI of the fiber by at least a selected amount. Again, without wishing to be bound by theory (except in a claim where explicitly claimed), it is considered that this may be beneficial for at least two reasons. Regarding the relaxation processes, noted above, that can lead to grating erasure, introducing an offset to the lower RI sections may allow the undesirable thermal decay to affect the lower RI sections as well as the higher RI sections, such that while the RI of both the higher RI sections and lower RI sections is reduced, the reduction in the Δn can be lessened because both lower and higher RI sections are affected. Regarding the unintentional selected “rewriting” of the grating noted above, because there are a range of defect sites involved in these processes, possible “photosensitive” sites can be depleted in the lower RI sections (whilst maintaining the ability to write a grating having required grating parameters, such as the Δn). By introducing the offset one can preferentially remove the bulk of the “low energy” sites that might otherwise result in grating erasure under the conditions of high radiation fluences to which the grating can be exposed during operation of the higher power device.

In another aspect, the invention provides a method of writing a grating in an optical fiber to facilitate the grating withstanding higher power operation, comprising providing a photosensitive optical fiber having a region having an original RI profile along the elongate direction of the fiber; exposing the optical fiber to actinic radiation to alter the original RI profile to form along a length of the fiber a grating having a RI profile including alternating higher RI and lower RI sections, “higher” and “lower” referring to the RI of a section relative to adjacent sections; and wherein the maximum RI difference between a refractive index of a higher RI section and a refractive index of an adjacent lower RI section of the RI profile of the grating is no greater than 85% of the difference between the average index of the RI profile of the grating and the original RI profile. The foregoing percentage can vary, as noted below.

The region can comprise, for example, the core of the optical fiber. Alternatively or additionally, the region can comprise the cladding of the optical fiber. Exposing can comprise a step of exposing at least a majority of the length to substantially the same dose (the product of radiation intensity and exposure time) of actinic radiation, and can further comprise a separate step of exposing the optical fiber with a pattern of actinic radiation wherein areas having a lower intensity than adjacent areas alternate with areas having a higher intensity than adjacent areas. Exposing can comprise exposing the optical fiber with a beam of radiation having an extent along the length that is less than the length and moving the beam of radiation in the elongate direction. Exposing can consist of a single step of exposing.

In another aspect, the invention provides an optical fiber article comprising an optical fiber comprising a region having an original RI profile along the elongate direction. A length of the elongate optical fiber can comprise an elongate grating having a RI profile including alternating higher refractive index and lower refractive index sections, where “higher” and “lower” refer to the refractive index of a section relative to adjacent sections. Regarding the RI profile of the grating, the maximum difference between a refractive index of a higher index section and a refractive index of an adjacent lower index section is no greater than 85% of the difference between the average index of the RI profile of the grating and the original RI profile. The foregoing percentage can vary, as noted below.

In yet a further aspect, the invention provides a method of writing a grating having higher power handling capability into an optical fiber, comprising providing a photosensitive optical fiber; exposing a length of the photosensitive optical fiber to actinic radiation so as to offset the RI profile of a region of the photosensitive optical fiber along the entire length of the photosensitive optical fiber by at least a selected amount; and, in a separate step, exposing the optical fiber to actinic radiation so as to form a grating in the optical fiber extending along at least a part of the length, and forming the grating including changing the refractive index of the region of the fiber along the length so as to include alternating sections of higher and lower refractive index along the length. The separate step can occur before or after exposing to offset the RI profile.

In yet another aspect, the invention provides a method of writing a grating into an optical fiber, comprising providing a photosensitive optical fiber; exposing a length of the optical fiber to actinic radiation to offset the refractive index of the fiber along the entire length by at least a selected amount; and exposing the photosensitive optical fiber to actinic radiation so as to form an elongate grating, exposing including directing at least two beams of energy at a selected angle to each other such that the beams interfere to expose at least part of the length of the optical fiber to alternating areas of higher and lower energy intensity. Exposing the optical fiber to change the index by the selected amount and exposing to form the grating can be performed in the same step, that is, at substantially the same time. Alternatively, exposing the optical fiber to change the index by the selected amount and exposing to form the grating can be performed at different times. The elongate grating includes alternating higher refractive index and lower refractive index sections, “higher” and “lower” referring to the refractive index of a section relative to adjacent sections, wherein the selected amount is at least 10% of the maximum difference between the refractive index of a higher index section and an adjacent lower index section of the grating.

In various practices of the methods and articles of the foregoing aspects of the invention the maximum RI difference between a refractive index of a higher RI section and a refractive index of an adjacent lower RI section of the RI profile can be no greater that 80%, no greater than 70%, no greater than 60%, no greater than 50%, or no greater than 40% of the difference between the average index of the RI profile of a grating and the original RI profile. The RI profile of the grating can comprise at least one of an apodized profile and a chirped profile.

In various practices of the methods and articles of the foregoing aspects of the invention the selected amount can be 20%, 40%, or 50% of the maximum difference between the refractive index of a higher index section and an adjacent lower index section of the grating. In various practices of the methods and articles of the foregoing aspects of the invention the selected amount can be at least 1×10⁻⁵; at least 5×10⁻⁵; at least 1×10⁻⁴; and at least 5×10⁻⁴. The selected amount can be substantially the same along the entire length.

The term “light” as used herein, means, as understood by one of ordinary skill in the optical arts, the electromagnetic energy associated with the optical apparatus in question, and is not to be limited to, for example, wavelengths visible to the human eye, which is a definition that can be found in certain dictionaries intended for laypersons. “Multimode fiber”, as that term is used herein, means that at least the next highest mode from the fundamental LP mode of the fiber is not cutoff at the operating wavelength of the fiber and hence propagates. For a step index fiber or a fiber having an equivalent step index, a normalized frequency, or V-number, of greater than 2.405, can indicate that the fiber is multimode. For such a fiber having a round core, V-number=[(π)×(core diameter)×(core numerical aperture)]/[free space operating wavelength]. “Optical fiber”, as used herein, can include lengths of fiber spliced or otherwise optically coupled together. “Photosensitive”, as used herein, means that the RI of the region or material can be changed via exposure to actinic radiation.

### BRIEF DESCRIPTION OF THE DRAWINGS

FIG. 1 schematically illustrates in cross section a fiber including a grating according to one embodiment of the invention;

FIG. 2 schematically illustrates RI profiles corresponding to the fiber including the grating of FIG. 1;

FIG. 3 is a flow chart of one arrangement of steps that can be included in making a grating according to one embodiment of the invention;

FIGS. 4A-C illustrate apparatus than can be used in one or more of the steps shown in FIG. 3; and

FIG. 5 schematically illustrates one embodiment of a fiber laser that includes a grating according to the present invention.

### DETAILED DESCRIPTION

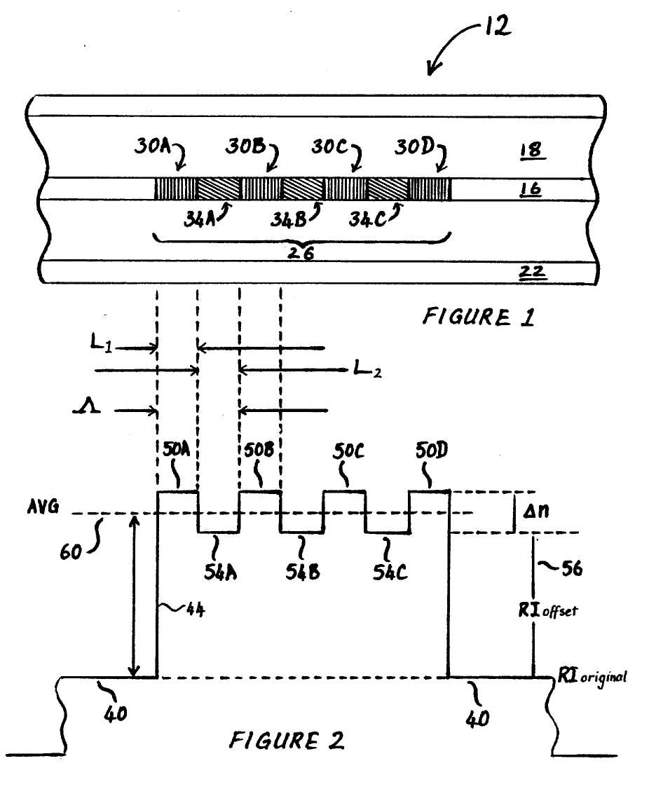

FIG. 1 schematically illustrates an optical fiber 12, shown in a cross sectional plane that includes the elongate axis of the fiber, that includes a region comprising a grating according to one embodiment of the invention. The optical fiber 12 comprises a core 16, a first cladding 18 disposed about the core, and a second cladding 22 disposed about the first, or inner, cladding 18. The optical fiber 12 also comprises a grating 26.

The grating 26 includes alternating sections of higher and lower refractive index (often abbreviated as “RI” herein). The sections of higher RI are indicated by vertical stripes and by reference numerals 30A, 30B, 30C and 30D, and the sections of lower RI are shown as diagonal stripes and are indicated by reference numerals 34A, 34B, and 34C. For simplicity of presentation, only four sections (30A-30D) of higher RI are shown in FIG. 1. As is appreciated by one of ordinary skill in the art, typically a grating will include significantly more than four such sections for higher index (and, accordingly, more sections of lower RI interposed between the higher index sections). If not otherwise specifically further qualified herein, the terms “higher” and “lower”, as used herein in reference to the RI of the alternating sections of a grating, refer to the refractive index of a section relative to its adjacent sections. “Higher” and “lower” are not meant to refer to the RI of the sections relative to an original refractive index of a region of the fiber into which the grating is written. Typically the RI of all of the sections of a grating when written according to the invention will be different (e.g., higher) than the original refractive index.

FIG. 2 schematically illustrates RI profiles corresponding to the fiber 12 including the grating 26. The core 16 comprises an original RI profile, as indicated by reference numeral 40. The grating 26 comprises the RI profile 44, which includes alternating sections of higher and lower RI. Sections 50A, 50B, 50C and 50D of the RI profile correspond, respectively, to sections 30A, 30B, 30C and 30D of the grating 26. Sections 54A, 54B and 54C correspond to sections 34A, 34B and 34C, respectively. As indicated in FIG. 2, the RI profile 44 includes an offset 56 such that the refractive indices of one or more of the lower index sections 54A-54C is not substantially equal to the original RI 40 of the region of the fiber in which the grating is written. The RI difference between a higher index section and an adjacent lower index section is denoted as Δn. Reference numeral 60 indicates the average RI of the RI profile 44 of the grating 26. For a large number of alternating higher index and lower index sections, where the length L₁ of the higher index sections is substantially the same as the length L₂ of the lower index sections (which is typically the case), the average RI will be substantially midway between the lower refractive indices 54A-54C and the higher refractive indices 50A-50D.

In the grating 26 shown in FIG. 1, the spacing A between adjacent higher RI sections (also known as the “pitch” of the grating) is substantially the same for all the higher RI sections of the grating. The Δn is also substantially the same, as is the RI offset. FIGS. 1 and 2 are exemplary, and one or more of the foregoing can vary along the grating according to various practices of the invention. Apodized gratings, in which the Δn is selectively varied along the length of the grating, as well as chirped gratings, in which the pitch A varies, are known in the art. Also, in many practical applications of the invention the offset 56 may not be the same at all locations along the grating. In some instances the offset may have a distribution along the grating. For example, the offset 56 can have a Gaussian distribution and accordingly will be larger near or at the center of the gratings than at the ends of the grating. Because the offset 56 may not be the same at all locations along the length of the grating 26, it can be more appropriate to state that there is at least a selected amount of RI offset from the original RI 40 along at least part of the grating 26.

By way of example, and not limitation to only the following, in various practices of the invention the selected amount can be 10%, 20%, 40%, or 50% of the maximum difference between the RI of a higher RI section and an adjacent lower RI section of the grating. In various practices of the invention the selected amount can be, in absolute rather than relative terms, a RI change of at least 1×10⁻⁵; at least 5×10⁻⁵; at least 1×10⁻⁴; and at least 5×10⁻⁴. The selected amount can be substantially the same along the entire length of the grating 26. The entire length of the grating 26 can be offset by a least the selected amount.

In certain practices of the invention, the maximum difference between a RI of a higher RI section and a RI of adjacent lower RI section (in the embodiment of the invention shown in FIG. 1 the maximum different is the same as the minimum, which are both equal to Δn) is no greater than a selected constant K times the difference between the average index of the RI profile of the grating and the original RI of the region of the fiber. Put into an equation:

Max Δn≦K×(Average RI grating−RI original)

For example, the maximum RI difference between a higher RI section and an adjacent lower RI section of the grating RI profile can be no greater that 85%, no greater than 80%, no greater than 70%, no greater than 60%, no greater than 50%, no greater than 40%, no greater than 30%, or no greater than 25% of the difference between the average index of the grating RI profile and the original RI. One of ordinary skill understands that the RI profile is often more sinusoidal than the “square wave” of exemplary FIG. 2, and that the RI of the higher and lower index sections may not be constant throughout a section. Maximum Δn is taken as the Δn for the adjacent sections that yield the largest difference between the highest RI of the higher index section and the lowest RI of the adjacent lower index section.

The interferometric technique, which is much more versatile than the phase mask technique for writing a grating, is understood to write a grating having practically no offset, as the original RI of the fiber is typically unchanged in the lower RI sections of the grating. The phase mask technique is understood to introduce some RI change to the lower RI sections (apparently in some phase masks as much as 40% of the light that is incident on the phase mask can be in the zero order). However, the current understanding of the Applicant is that the RI change of the lower RI grating sections relative to the original RI of the fiber is considered according to the prior art as an undesirable artifact of the phase mask technique and is to be minimized and avoided.

In the embodiment of the invention shown in the FIG. 1, the core 16 comprises the grating 26. In other embodiments of the invention, a cladding, such as the cladding 18, can comprise a grating (e.g., an angled grating for coupling pump light into or out of the inner cladding 18), or both the core 16 and the cladding 18 can be considered to comprise a grating (e.g., a grating that is written into the core 16 and at least part of the inner cladding 18, which can be useful for suppressing cladding modes and accordingly improve for certain applications the optical properties of the grating).

The first cladding 18 tends to confine light propagated by the core 16 to the core 16, while the second cladding 22 tends to confine light propagating in the inner cladding 18 to the inner cladding 18. The optical fiber 12 can be a conventional fiber in its entirety, wherein all of the material of the first cladding 18 has a refractive index that is less than the refractive index of all of the material of the core 16, and wherein the all of the material of the second cladding 22 has a refractive index that is less than the refractive index of all of the material of the inner cladding 18. The fiber can also, in whole or in part, comprise photonic bandgap or microstructured regions, such as the core, inner cladding, or second cladding, which also confine light to a region of the fiber so as to allow guidance of light by that region.

Although in the embodiment shown in FIG. 1 the optical fiber 12 comprises a double-clad, or cladding-pumped, optical fiber, one of ordinary skill in the art, in light of the disclosure herein, understands that the invention is certainly not so limited and is useful in fibers having fewer and or additional claddings.

It can be difficult to directly measure certain properties of the RI profile of the grating, such as Δn and the average RI. It is common in the art for these quantities to be determined from spectral measurements of the grating and known writing parameters. For example, for an FBG, the average RI of the grating RI profile can be related to one or both of the wavelength of peak reflectivity of the grating and the pitch of the grating, Λ. The wavelength of peak reflectivity can be measured and the pitch Λ is one of the parameters known from the writing of the grating. The Δn can be related to a measurement of the magnitude of the peak reflection. The technique of determining average RI and Δn from a combination of writing parameters and measurements also can be applied to more complex gratings, such as apodized (where there is a maximum Δn) or chirped gratings. Fitting to computer models may aid the process of determining average RI and Δn. Coupled-mode theory techniques are well established and are the preferred method for use in conjunction with determining the average RI and the Δn of a grating refractive index profile of the invention. Regarding a general overview of such techniques, see, for example, Chapter 5 of Fiber Bragg Gratings: Fundamentals and Applications in Telecommunications and Sensing, by Andreas Othonos and Kyriacos Kalli, Artech House, Boston, 1999 (ISBN 0-89006-344-3).

A grating of the invention is understood to be particularly useful in large mode area (LMA), Double Clad (DC) fibers. Such fibers can have a core having a diameter exceeding, for example, 15 microns and a numerical aperture of no greater than, for example, 0.09. The inner cladding can be a pump cladding, having a diameter of, for example, greater than 300 microns. The core can be multimode at the wavelength of operation of the fiber, and can have a V-number, for example, of 3.5 or greater. The wavelength of operation of the fiber typically comprises the wavelength at which a rare earth dopant comprised by the fiber or another fiber in optical communication with the fiber emits radiation responsive to be pumped by optical energy having a different wavelength. If modal properties are of interest in the use of coupled mode theory noted above, the modal properties of the mode the grating is primarily intended to affect (e.g., reflect) are to be used. In fiber that is operated in the single mode regime, the grating is typically primarily intended to affect the fundamental, or LP₀₁, mode. This is often the case for a multimode fiber as well, and in particular is typically the case for LMA fibers. In certain instances, such as the fiber amplifiers designed to use the Higher Order Mode (HOM) technique wherein energy is deliberately converted (by, for example, a long period grating) to a higher order mode (e.g., LP₀₇) for amplification, the mode the grating is primarily intended to affect is not the fundamental mode but the higher order mode.

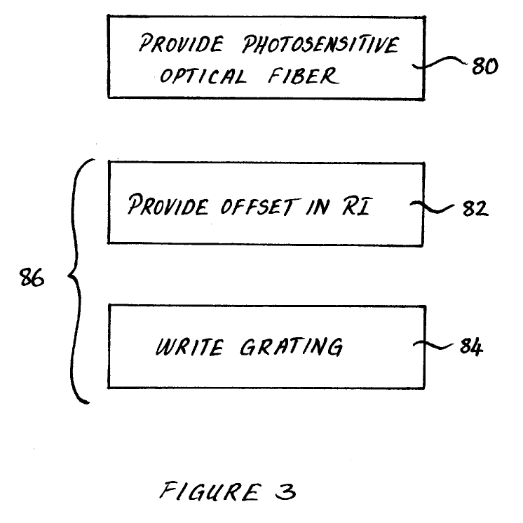

FIG. 3 is a flow chart of one arrangement of steps that can be included in making a grating according to one embodiment of the invention. As indicated by reference numerals 80 and 82, a photosensitive optical fiber can be provided and an offset provided in the RI of a region (e.g., the core) of the optical fiber. The grating can include all or part of the length of the fiber over which the offset was written. The length of the grating can be coextensive with, or be shorter or longer than, the length of the region over which the offset is written. Providing the offset can include exposing a length of the fiber with actinic radiation having substantially constant intensity. Writing the grating can be a separate step of exposing the fiber with radiation wherein areas having a lower intensity than adjacent areas alternate with areas having a higher intensity than adjacent areas.

Step 82, providing an offset in the RI can occur during a time period that overlaps with or is coextensive with step 84, writing the grating. Steps that do not substantially overlap in time are considered separate steps. Steps 82 and 84 can be combined so as to consist together of a single step of exposing. The order of steps 82 and 84 can be interchanged, such that step 84 occurs before step 82.

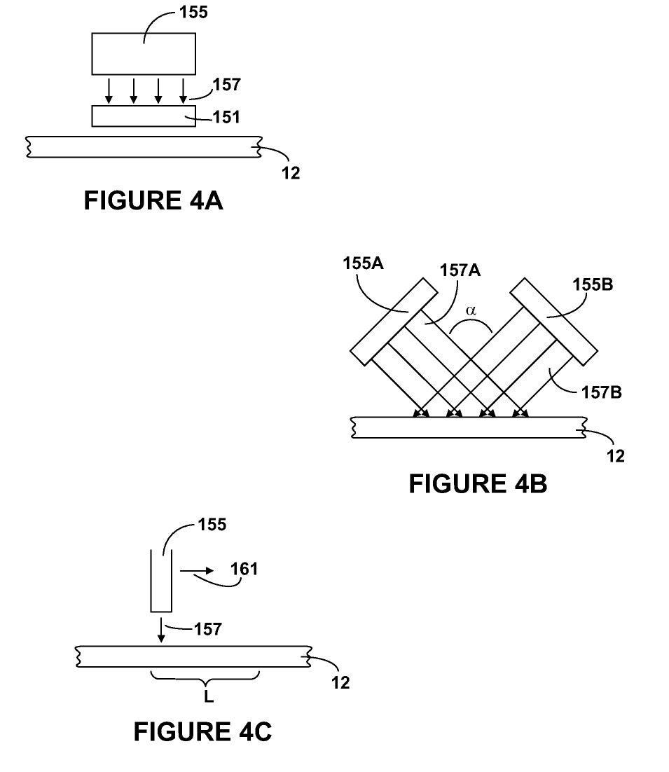

FIGS. 4A-4C schematically illustrate an apparatus than can be used in one or more of the steps shown in FIG. 3. FIG. 4A depicts a mask 151, which can be a phase mask, interposed between the source of actinic radiation 155 and the optical fiber 12. The mask 151 receives the beam of actinic radiation 157 from the source of actinic radiation 155 for exposing the optical fiber 12 to a pattern of actinic radiation of alternating higher and lower intensity areas. The source 155 can expose the optical fiber 12 directly, that is, without the mask 151 interposed between the source 155 and the optical fiber 12, for providing a desired offset in the RI profile of the grating written into the optical fiber 12. In FIG. 4B, first and second sources of actinic radiation, 155A and 155B respectively, direct first and second beams, 157A and 157B, such that the beams intersect at the angle α and interfere to expose the fiber 12 to a pattern of actinic radiation having alternating areas of higher and lower energy intensity. One of the beams can be of a higher intensity than the other of the beams such that the interference does not create perfect null areas, thereby providing an offset in the RI of the grating being written of at least a selected amount from the original RI of the optical fiber 12. The selected amount of the offset can be a function of the difference in the intensities of the two beams. FIG. 4C schematically illustrates a source of actinic radiation 155 that is not coextensive with the length L of the grating to be written in the optical fiber 12. The source 155 is scanned along the fiber and appropriately modulated to selectively expose the fiber to write a grating in the fiber. The modulation can be such that the grating can include an appropriate offset. Alternatively or additionally, the source can be scanned without modulation to facilitate creation of an appropriate grating offset. It is noted that although FIG. 4A depicts the source 155 as providing a beam 157 that is being coextensive with the mask 151, this need not be the case and the source can be moved to scan the beam along the mask 151.

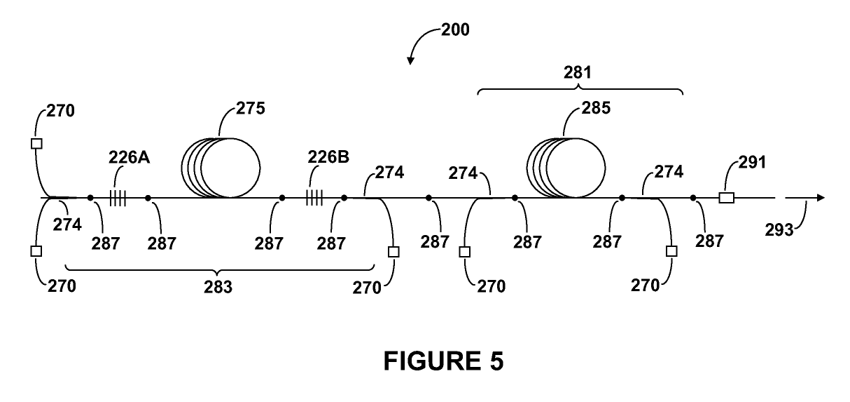

FIG. 5 schematically illustrates one embodiment of an optical fiber laser 200 that includes a pair of gratings 226A and 226B according to the present invention. The optical fiber laser 200 can include pump sources, such as the pump diodes 270. The fiber optic couplers 274 couple the pump diodes 270 to the optical fiber laser 200. The gratings 226A and 226B can define an optical fiber laser cavity therebetween. The optical fiber laser cavity can include a length of active fiber 275, where the active material can comprise rare earth ions. The fiber laser 200 can include a second stage 281 that amplifies the output of the first stage 283 and that includes a second length of active fiber 285. Reference numerals 287 indicate typical locations wherein lengths of fiber are spliced together. The optical fiber laser 200 can include a “pump dump” 291 for removing unabsorbed pump light from the output beam 293. The first stage 283 of the optical fiber laser 200 can comprise a Q-switch, such as a Q-switch within the laser cavity defined by the optical fiber gratings 226A and 226B. It is noted that the fiber laser 200 need not include a pair of gratings to define a laser cavity; as known in the art are both distributed feedback (DFB) and distributed Bragg reflection (DBR) cavity designs, and a single grating can be used in a laser, especially when narrow output linewidth is desired.

Several embodiments of the invention have been described and illustrated herein. Those of ordinary skill in the art will readily envision a variety of other means and structures for performing the functions and/or obtaining the results or advantages described herein and each of such variations or modifications is deemed to be within the scope of the present invention. More generally, those skilled in the art would readily appreciate that all parameters, dimensions, materials and configurations described herein are meant to be exemplary and that actual parameters, dimensions, materials and configurations will depend on specific applications for which the teachings of the present invention are used. It is therefore to be understood that the foregoing embodiments are presented by way of example only and that within the scope of the appended claims and equivalents thereto; the invention may be practiced otherwise than as specifically described.

In the claims as well as in the specification above all transitional phrases such as “comprising”, “including”, “carrying”, “having”, “containing”, “involving” and the like are understood to be open-ended. Only the transitional phrases “consisting of” and “consisting essentially of” shall be closed or semi-closed transitional phrases, respectively, as set forth in the U.S. Patent Office Manual of Patent Examining Procedure §2111.03, 8^{th} Edition, Revision 5.

It is understood that the use of the term “a”, “an” or “one” herein, including in the appended claims, is open ended and means “at least one” or “one or more”, unless expressly defined otherwise. The occasional use of the terms herein “at least one” or “one or more” to improve clarity and to remind of the open nature of “one” or similar terms shall not be taken to imply that the use of the terms “a”, “an” or “one” alone in other instances herein is closed and hence limited to the singular. Similarly, the use of “a part of”, “at least a part of” or similar phrases (e.g., “at least a portion of”) shall not be taken to mean that the absence of such phrases elsewhere is somehow limiting. For example, consider that it is disclosed that a fiber is initially etched along a length and then part or all of the etched length is bonded to a substrate. The phrase “said fiber including a length that is etched to have a reduced diameter, at least a part of said etched length bonded to said substrate”, makes it clear that not all of the etched length need be bonded to the substrate. However, the phrase “a fiber having an etched length, said etched length being bonded to said substrate”, also is not intended to require that all of the initially etched length be bonded to the substrate, regardless whether or not “at least a part of” is used is similar recitations elsewhere in the specification or claims or not.

Having described the invention, what is claimed as new and to be secured by Letters Patent is:

1. A method of writing a grating having higher power handling capability into an optical fiber, comprising:
providing a photosensitive optical fiber;
exposing a length of the photosensitive optical fiber to actinic radiation so as to offset the refractive index profile of a region of the photosensitive optical fiber along the entire length of the photosensitive optical fiber by at least a selected amount; and
in a separate step, exposing the optical fiber to actinic radiation so as to form a grating in the optical fiber extending along at least part of the length, forming the grating including changing the refractive index of the region of the fiber so as to include alternating sections of higher and lower refractive index along the length.

2. The method of claim 1 wherein the separate step occurs before the exposing to offset the refractive index profile.

3. The method of claim 1 wherein the separate step occurs after the exposing to offset the refractive index profile.

4. The method of claim 1 wherein the selected amount is at least 1×10⁻⁵

5. The method of claim 1 wherein the selected amount is at least 5×10⁻⁵

6. The method of claim 1 wherein the selected amount is at least 1×10⁻⁴

7. The method of claim 1 wherein the selected amount is at least 5×10⁻⁴.

8. The method of claim 1 wherein the selected amount is substantially the same along the entire length.

9. A method of writing a grating into an optical fiber, comprising:
providing a photosensitive optical fiber;
exposing a length of the optical fiber to actinic radiation to offset the refractive index of the fiber along the entire length by at least a selected amount; and
exposing the photosensitive optical fiber to actinic radiation so as to form an elongate grating, exposing including directing at least two beams of energy at a selected angle to each other such that the beams interfere to expose at least part of the length of the fiber to alternating areas of higher and lower energy intensity.

10. The method of claim 9 wherein exposing the optical fiber to change the index by the selected amount and exposing to form the grating are performed at substantially the same time.

11. The method of claim 9 wherein exposing the optical fiber to change the index by the selected amount and exposing to form the grating are performed at different times.

12. The method of claim 9 wherein the elongate grating includes alternating higher refractive index and lower refractive index sections, “higher” and “lower” referring to the refractive index of a section relative to adjacent sections; and wherein the selected amount is a least 10% of the maximum difference between the refractive index of a higher refractive index section and an adjacent lower refractive index section of the grating.

13. The method of claim 9 wherein the selected amount is at least 20% of the maximum difference between the refractive index of a higher refractive index section and an adjacent lower refractive index section of the grating.

14. The method of claim 9 wherein the selected amount is at least 40% of the maximum difference between the refractive index of a refractive higher index section and an adjacent lower refractive index section of the grating.

15. The method of claim 9 wherein the selected amount is at least 50% of the maximum difference between the refractive index of a higher refractive index section and an adjacent lower refractive index section of the grating.

16. The method of claim 9 wherein the selected amount is at least 1×10⁻⁵.

17. The method of claim 9 wherein the selected amount is at least 5×10⁻⁵.

18. The method of claim 9 wherein the selected amount is at least 1×10⁻⁴.

19. The method of claim 9 wherein the selected amount is at least 5×10⁻⁴.
